(19) United States
(12) Patent Application Publication
(10) Pub. No.: US 2015/0325731 A1
(43) Pub. Date: Nov. 12, 2015

(54) BI-COMPONENT ELECTRICAL CONNECTOR

(71) Applicant: DOW GLOBAL TECHNOLOGIES LLC, Midland, MI (US)

(72) Inventors: Abhijit A. Namjoshi, Midland, MI (US); Rebekah K. Feist, Midland, MI (US); Leonardo C. Lopez, Midland, MI (US); Michael E. Mills, Midland, MI (US); Lindsey A. Clark, Midland, MI (US); Kevin P. Capaldo, Midland, MI (US)

(21) Appl. No.: 14/410,347

(22) PCT Filed: Aug. 9, 2013
(86) PCT No.: PCT/US13/54256

§ 371 Date: Dec. 22, 2014

Related U.S. Application Data
(60) Provisional application No. 61/683,459, filed on Aug. 15, 2012.

(51) Int. Cl. H01L 31/05

(52) U.S. Cl. CPC H01L 31/0516; H01L 31/0512

(57) ABSTRACT

The invention relates to a photovoltaic article comprising a plurality of photovoltaic cells having first (22) and second (24) electrical connector segments in contact with the top side (18) of a first cell (10) and the backside (16) of a second adjacent cell (12). The materials used to form the electrical connector segments are selected to minimize corrosion, maximize contact area, and lower contact resistance over the lifetime of the article.

### FIELD OF THE INVENTION

This invention relates generally to photovoltaic cells including electrical connector segments and associated conductive materials and coatings formed for improving electrical contact between cell surfaces and adjacent layers.

### BACKGROUND OF THE INVENTION

It is common for photovoltaic cells to be connected in series by an electrical connector substrate that contacts the front side of a first cell and the backside of an adjacent cell. Such configurations are commonly used with flexible photovoltaic cells such as copper chalcogenide type cells (e.g. copper indium gallium selenides, copper indium selenides, copper indium gallium sulfides, copper indium sulfides, copper indium gallium selenides sulfides, etc.), amorphous silicon cells, crystalline silicon cells, thin-film III-V cells, thin-film II-VI cells, organic photovoltaics, nanoparticle photovoltaics, dye sensitized solar cells, and combinations of the like. Unfortunately, certain environmental stresses cause corrosion that reduces the electrical contact between the electrical connector and cell surfaces. The nature and source of the corrosion however, differs depending upon the composition of the cell surface and that of the electrical connector. This can be of particular concern since typically a single electrical connector having a consistent composition (i.e. Sn coated Cu ribbon or electrical connector) is used to bridge the top contact of one cell to the bottom contact of a subsequent cell. Thus, an attempt to prevent corrosion on the top side of a cell by selecting specific materials for the connector may result in a corrosive effect on the back side of the adjacent cell. In other words, an electrical connector formed of one consistent material along its entirety is unlikely to have a corrosion free connection with both the top side of one cell and backside of an adjacent cell.

US2005/0264174 describes OLED having stable intermediate connectors including a layer of a high-work-function metal and a layer of a metal compound. This reference indicates that use of a high-work-function metal layer provides for improved operational stability and improved power efficiency.

WO 2009/097161 teaches strings of cells that are electrically joined by conductive tabs or ribbons adhered with an electrically conductive adhesive on the front and back of adjacent cells. This reference indicates that selecting the coefficient of thermal expansion of the ribbon or tab to match the substrate material minimizes mechanical stresses decreasing the possibility of adhesion failure.

There continues to be a need for electrical connectors for use in photovoltaic cells to assist in maintaining electrical contacts within the cells over time by avoiding corrosion due to environmental stress. There is a further need for electrical connectors that include a variable material composition along the connector such that the material composition at any point along the electrical connector is selected and tuned for improved, connectivity with the cell surface that will be contacted. There is a further need for electrical connectors that are formed so that the surface of the connector that contacts a top side of a first cell is formed of a material that is dissimilar from that of the surf lice of the connector that contacts the backside of an adjacent cell.

### SUMMARY OF INVENTION

The present invention meets the aforementioned needs by providing an electrical connector including a plurality of electrical connector segments, each segment comprising at least one material that is dissimilar from that of adjacent segments. Each electrical connector segment preferably comprises a material that will promote conductivity and minimize corrosion when contacted by the particular cell surface to which the electrical connector segment will be connected. More specifically, a first electrical connector segment will include a surface formed of materials selected for improved connectivity with a top side of a first photovoltaic cell and a second electrical connector segment will include a surface formed of materials selected for improved connectivity with a backside of an adjacent photovoltaic cell. Further, the materials selected for each are preferably dissimilar materials. The improved connectivity may be a result of reduced corrosive reactions on the top side and/or the backside cell surface. Such corrosion is the result of environmental stress (e.g., exposure to heat, oxygen, and/or humidity) experienced over time by photovoltaic cell devices and appears to cause reduced performance within the cells. The specific corrosion mechanisms that occur on either the top side or the backside of the cell can be a result of unfavorable interactions between the materials on the cell as well as the material on the electrical connector segments. By providing electrical connector segments having materials specifically selected to improve connectivity with both the top side and backside contacts, corrosive reactions are minimized and electrical connectivity is improved between the cell-electrical connector segment interface over the lifetime of the photovoltaic cell assembly.

As an example, it may be possible that any surface of an electrical connector segment that will contact a top surface of the cell may be tuned to resist oxidation, whereas any surface of an electrical connector segment that will contact a bottom surface of a cell may be tuned to resist corrosion in the presence of corrosive species (e.g., selenium, sulfur, oxygen) present on the hack surface of the cell. Each electrical connector segment may be connected to or in electrical communication with one or more adjacent segments. It may provide additional benefit w select materials for each electrical connector segment haying a suitably low value for hardness, high electrical conductivity, or electrode potentials similar to the electrode potentials of the cell surfaces that each segment contacts, in an effort to improve adhesion and electrical connection between the electrical connector segments, cell surfaces and any associated adhesive layers.

Thus, according to one aspect, the teachings herein provide for an article comprising (i) one or more photovoltaic cells haying a first surface and a second opposing surface; (ii) a first electrical connector segment having a portion that contacts and is in electrical communication with the first surface of a first cell; (iii) a second electrical connector segment having a portion that contacts and is in electrical communication with the second surface of an adjacent cell and is in electrical communication with the first electrical connector; wherein the portion of the second electrical connector segment that contacts the second surface of the adjacent cell comprises a material that is dissimilar from the material comprising the portion of the first electrical connector segment that contacts the first surface of the first cell.

Preferably, the article is a string of at least two such photovoltaic cells where a first segment of the electrical connector segments is in contact with the top side electrode (the first surface) of the first photovoltaic cell and extends beyond the edge of that cell and is connected to a second electrical connector segment in contact with a backside electrode (the second surface) of an adjacent cell. More, preferably the article has three or more such cells each having a. plurality of electrical connector segments in contact with the backside electrode of one cell and also in contact with the front side electrode of an adjacent cell. The first and second electrical connector segments may be arranged so that while they may comprise one or more similar materials, the material of the first electrical connector segment that contacts a cell surface is dissimilar from the material of the second electrical connector segment that contacts a cell surface. More specifically, the materials of the first and second electrical connector segments may be arranged in a layered format so that a first layer contacts a surface of a first cell and the second layer contacts a surface of a second cell (e.g., a vertical arrangement of dissimilar materials). The first and second electrical connector segments may be formed so that they comprise no common materials, whereby the first electrical connector segment comprises one or more first materials and the second electrical connector segment comprises one or more second materials (e.g., a horizontal arrangement of dissimilar materials). The first electrical connector segment may thus be located in direct contact with the second electrical connector segment along only one edge of the first electrical connector segment.

In another embodiment the invention relates to a method for forming an article comprising: (i) contacting one or more photovoltaic cells having a first surface and a second opposing surface with a first electrical connector segment, wherein a portion of the first electrical connector segment contacts and is in electrical communication with the first surface of the one or more cells; (ii) contacting the second surface of the one or more cells with a second electrical connector segment so that a portion of the second electrical connector segment is in electrical communication with the second surface of the one or more cells; wherein the portion of the first electrical connector segment that contacts the first surface of the one or more cells comprises a material that is dissimilar from the portion of the second electrical connector segment that contacts the second surface of the one or more cells.

The present teachings meet the aforementioned needs by providing an electrical connector that is formed to minimize corrosion on both the top side and backside of a photovoltaic cell. The electrical connector does so by providing first and second electrical connector segments whereby the material of the surface of the first segment that contacts the cell is dissimilar from the material of the surface of the second segment that contacts the cell. The advantage of the teachings herein is reflected in the stability of the photovoltaic cells when exposed to environmental stress. The selection of materials for forming electrical connection segments having dissimilar metallurgy results in improved resistance to corrosive effects on cell surfaces which leads to improved function of the cells, especially over extended periods of time.

### BRIEF DESCRIPTION OF THE DRAWINGS

FIG. 1 is a cross-sectional view showing a representative first electrical connector segment and an adjacent second electrical connector segment connecting one cell to an adjacent cell.

FIG. 2 is a cross-sectional view showing a representative first electrical connector segment in direct planar contact with a second electrical connector segment connecting one cell to an adjacent cell.

FIG. 3 is a cross-sectional view showing a representative first electrical connector segment having a first coating and a second electrical connector segment having a second coating connecting one cell to an adjacent cell.

FIG. 4 is a cross-sectional view showing a representative first electrical connector segment having a first coating on one surface and a second coating on an opposing surface and a second electrical connector segment having a first coating on one surface and a second coating on an opposing surface connecting one cell to an adjacent cell.

FIG. 5 is a cross-sectional view showing a representative first electrical connector segment having a first coating on one surface and a second electrical connector segment having a first coating on one surface and a second coating on an opposing surface connecting one cell to an adjacent cell.

### DETAILED DESCRIPTION

The present teachings relate to an electrical connector including a plurality of electrical connector segments, each segment comprising at least one material that is dissimilar from that of adjacent segments. Each electrical connector segment preferably comprises a material that will promote conductivity and minimize corrosion at photovoltaic cell surfaces. This application is claims priority from U.S. Provisional Application Ser. No. 61/683,459 filed Aug. 15, 2012 which is incorporated herein by reference in its entirety for all purposes.

The photovoltaic cells used in this invention may be any photovoltaic cells used in the industry. Examples of such cells include crystalline silicon, amorphous silicon, CdTe, GaAs, dye-sensitized solar cells (so-called Gratezel cells), organic/polymer solar cells, or any other material that converts sunlight into electricity via the photoelectric effect. However, the photoactive layer is preferably a layer of IB-IIIA-chalcogenide, such as IB-IIIA-selenides, IB-IIIA-sulfides, or IB-IIIA-selenide sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS). These can also be represented by the formula CuIn(1−x)GaxSe(2−y)Sy where x is 0 to 1 and y is 0 to 2. The copper indium selenides and copper indium gallium selenides are preferred. CIGSS cells usually include additional electroactive layers such as one or more of emitter (buffer) layers, conductive layers (e.g. transparent conductive layer used on the top side) and the like as is known in the art to be useful in CIGSS based cells are also contemplated herein. The cells discussed herein may be utilized to form shingle structures or laminates.

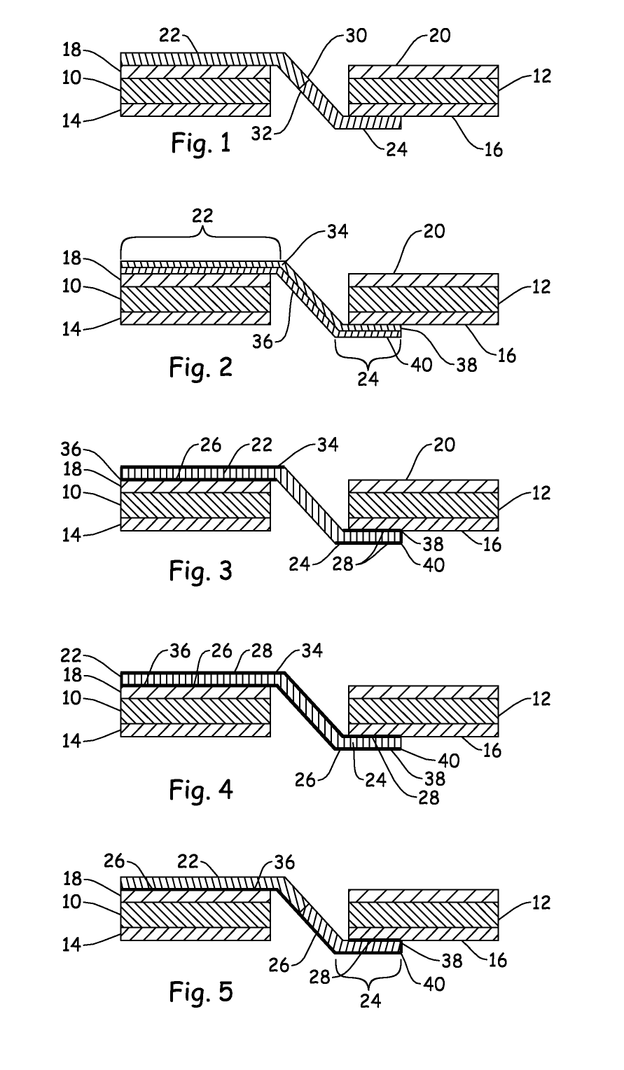

The photovoltaic cells each include a backside electrode, including the substrate 16 of the second cell (the second surface of the one or more cells) as depicted in FIGS. 1-5. Typically the substrate associated with the backside electrode will comprise metal foils or films or will be such a foil, film or a metal paste or coating on a non-conductive or conductive substrate. Suitable materials include, but are not limited to metal foils or films of stainless steel, aluminum, titanium or molybdenum. Preferably, the electrode structure including the substrate is flexible. The substrate can be coated with optional backside electrical contact regions on one or both sides of the substrate. Such regions may be formed from a wide range of electrically conductive materials, including one or more of Cu, Mo, Ag, Al Cr, Ni, Ti, Ta, Nb, W combinations of these, and the like. Conductive compositions incorporating Mo may be used in an illustrative embodiment. Trace amounts or more of chalcogen containing substances may be found on the backside electrode surface, particularly when the photoactive layer is a IB-IIIA chalcogenide. These chalcogen substances may be residual from the formation process of the photoactive layer. The propensity of these materials to corrode make it desirable to select materials for the electrical connector segments (22, 24 as depicted in FIGS. 1-5) that will not only aid in preventing corrosion, but also promote electrical contact between the electrical connector and cell surface. This improved bond strength may altogether eliminate any need for additional adhesives (ECAs, PCAs and other adhesives).

Each cell will also have a top side electrical collection system comprising a front electrode and including the top contact layer 18 as shown in FIGS. 1-5. The top contact layer serves to collect photogenerated electrons from the photoactive region. The top side electrical contact or top contact layer (also referred to as TCL) is formed over the photoactive region on a light incident surface of the photovoltaic device. The TCL has a thickness of at least about 10 nm, or even at least about 100 nm. The TCL has a thickness of about 1500 nm or less, preferably at about 600 nm or less. The TCL may be a very thin metal film that has transparency to the relevant range of electromagnetic radiation or more commonly is a transparent conductive oxide (TCO). A wide variety of transparent conducting oxides (TCO) or combinations of these may be used, including any TCOs that allow for effective collection of electrons and form electrical contacts with the electrical connector segments described herein. Examples include fluorine-doped tin oxide, tin oxide, indium oxide, indium tin oxide (ITO), aluminum doped zinc oxide (AZO), gallium doped zinc oxide, zinc oxide, combinations of these, and the like. In one illustrative embodiment, the TCO region is indium tin oxide. TCO layers are conveniently formed via sputtering or other suitable deposition technique. Thus, an electrical connector segment that contacts the top contact layer will be formed of materials selected to improve electrical conductivity with the TCO or any other material that may be contacted on the top surface of each cell.

As a specific example, a backside electrode may include a substrate having a selenide, sulfide, or telluride content as a result of the formation processes described above. In order to achieve a desired electrical contact, an electrical connector segment in accordance with the present teachings (e.g., the second electrical connector segment) may be utilized having specific metallurgy for bonding to the selenide, sulfide or telluride of the cell surface. Such electrical connector materials and or coatings may include but are not limited to tin, copper, silver, gold, platinum, aluminum, molybdenum, zinc, antimony, niobium, chromium, nickel, indium, lead, iron, steel, stainless steel, TiN, TaN, SnO₂, doped SnO₂, ITO, AZO, doped ZnO, graphene, conductive organic polymers, conductive small molecules or any combination thereof. More specifically, preferred materials for the second electrical connector segment include tin, copper, silver, gold, niobium, molybdenum, or combinations thereof. Preferably, the material for forming the surface of the electrical connector segment that contacts the backside substrate may be selected that are matched to the material forming the backside substrate, or are relatively inert. In one specific example, the backside substrate may include a selenium layer and the electrical connector segment may include Sn or be coated with Sn, such that a SnSe contact is formed. Thus, an electrical connector segment that contacts the backside substrate will be formed of materials selected to improve electrical conductivity with the substrate forming the backside electrode.

As an additional example, a top contact layer may comprise a transparent conducting oxide as a result of the formation processes described herein. In order to achieve a desired electrical contact, an electrical connector segment in accordance with the present teachings (e.g., the first electrical connector segment) may be utilized having specific metallurgy for bonding to the top contact layer. Such electrical connector materials and/or coatings may include but are not limited to tin, copper, silver, gold, platinum, aluminum, molybdenum, zinc, antimony, niobium, chromium, nickel, indium, lead, iron, steel, stainless steel, TiN, TaN, SnO₂, doped SnO₂, ITO, AZO, doped ZnO, graphene, conductive organic polymers, conductive small molecules or any combination thereof. More specifically, preferred materials for the first electrical connector segment include tin, silver, indium, or combinations thereof. Preferably, the material for forming the surface of the electrical connector segment that contacts the top contact layer is a relatively soft material.

The electrical connector may include a plurality of electrical connector segments such that a first electrical connector segment extends beyond an edge of the top side surface of a cell and is contacted with a second electrical connector segment that extends beyond an edge of the backside surface of an adjacent cell thus forming the electrical connector. More preferably as shown in FIGS. 1 through 5, the electrical connector forms an interconnect element between two adjacent cells. The interconnecting electrical connector (each electrical connector segment) may include a substantially solid material or a material that includes voids. The material containing voids may be in the form of a mesh structure and the like. The mesh structure (which may include a plurality of mesh segments corresponding to the electrical connector segments) may receive a coating on one or more mesh segments and one or more mesh segments may be substantially free of any coating. In one preferred embodiment, the mesh may be a copper mesh and may be coated with tin. The mesh may be a copper mesh and coated with an electrically conductive adhesive.

As taught herein, one or more of the first and second electrical connector segments may be formed of a coating material. As such, any coated electrical connector segment includes a core material onto which the coating is located. A material coating may be located onto only a portion of the core material or may substantially cover the entire core material. Examples showing arrangements for coating materials and associated core materials are shown at FIGS. 3-5. As shown in FIGS. 3-5 and as discussed herein, the coating materials may he selected so that the coating material that contacts a top side contact of a first cell is dissimilar from a coating that contacts the backside substrate of an adjacent second cell. Alternatively, only one of a first and second electrical connector segment may include a material coating while the other segment remains substantially free of any coating. As mentioned above, the coatings may include an adhesive, which may be an electrically conductive adhesive. Materials selected for the coatings may include but are not limited to tin, copper, silver, gold, platinum, aluminum, molybdenum, zinc, antimony, niobium, chromium, nickel, indium, bismuth, lead, iron, steel, stainless steel, TiN, TaN, SnO₂, doped SnO₂, TO AZO, doped ZnO, graphene, conductive organic polymers, conductive small molecules or any combination thereof. One or both of the first electrical connector segment and second electrical connector segment are formed of a coating selected from molybdenum, tin, silver, bismuth, and combinations thereof.

Materials comprising the core material are preferably highly conductive and selected to match the material selected for the coating. Such materials may include but are not limited to copper, silver, brass, gold, or combinations thereof. Conductive alloys of these materials may be utilized as well, including but not limited to alloys containing tin, iron, and the like.

At least a portion of one or both of the first electrical connector segment and second electrical connector segment may comprise a polymeric insulating material located in physical proximity to the first surface, second surface, or both of the one or more cells. One or both of the first electrical connector segment and second electrical connector segment may be formed with a coating that forms an electrical contact at temperatures below 200° C.

The materials for forming each electrical connector segment may preferably be selected for forming an ohmic contact, where the work function difference between the two materials is most preferably about 0.5 eV or less, between a surface of an electrical connector segment and a cell surface. However, in certain arrangements the materials may be selected for forming a blocking contact, where the work function difference between the two materials is about 0.5 eV or more, between a surface of an electrical connector segment and a cell surface. Such blocking contacts are known as, for example metal-Schottky or metal-insulator-semiconductor (MIS) contacts or the like. More specifically, the selected materials in a blocking contact may result in a doped contact region and may require the addition of one or more coatings to the electrical connector segments. The nature of the contact may be a direct result of relative similarities of the work function values for the selected electrical connector segment materials.

Additional adhesives (beyond those utilized for forming the electrical connector segments) such as electrically conductive adhesives (ECAs), pressure sensitive adhesives (PSAs) or other adhesives may or may not be included, given that the electrical contact formed between the electrical connector segments and cell surfaces may be such that an additional adhesive is no longer necessary. However, one or more coatings for forming the first and/or second electrical connector segment may include an electrically conductive adhesive. Any adhesive included may be located in between one or more lavers within the cells (e.g., between one or more substrates for forming the backside substrate or top contact layer). Such adhesives may be located in between the substrate for forming the backside electrode or top contact layer and the first or second electrical connector segments. Such ECA's are frequently compositions comprising a thermosetting polymer matrix with electrically conductive particles dispersed therein. Such thermosetting polymers include but are not limited to thermoset materials comprising epoxy, cyanate ester, maleimide, phenolic, anhydride, vinyl, allyl or amino functionalities or combinations thereof. The conductive filler particles may be any particles which are sufficiently capable of conducting electric current such as silver, gold, copper, nickel, carbon nanotubes, graphite, tin, tin alloys, bismuth or combinations thereof.

As discussed herein, the performance of the cells or modules under environmental stresses such as damp heat, dry heat or thermal cycling is enhanced if the electrical connector segments are formed and applied so that the surface of the electrical connector that contacts the top contact layer of the cell (the first electrical connector segment) has a different composition than the surface of the electrical connector that contacts the backside substrate of the cell (the second electrical connector segment). Preferably, the materials fir forming each of the first and second electrical connector segments (or the surfaces of each electrical connector segment that will contact a cell surface) will be selected from having similar work function values within about 0.8 eV or less, or more preferably within about 0.5 eV or less of the cell surface materials that each connector segment is in contact with, Preferably, the materials for forming each of the first and second electrical connector segments (or more specifically, the surfaces of each electrical connector segment that will contact to cell surface) will be selected from metallic materials having similar work function values within about 0.8 eV or less, or more preferably within about 0.5 eV or less of one another. It is further desirable that the materials be selected so that the hardness of each electrical connector segment is relatively low, for forming higher contact areas and thus lower initial contact resistance between the cell surfaces and the suffices of the electrical connector segments. For example, the material of the first electrical connector that contacts the top contact layer is about 300 MPa or less (on the Vickers hardness scale). The material of the second electrical connector that contacts the top contact layer is about 600 MPa or less or more preferably 300 MPa or less. Likewise, it is desirable that the materials be selected so that the hardness of the cell surface materials (the top contact layer and backside substrate) that each connector segment is in contact with is about 600 MPa or less, or even 300 MPa or less.

In addition to the selection of materials based upon low hardness values and similar work function values, it is also desirable that the electrode potentials of the electrical connector segments be within about 0.65V, or less, more preferably within about 0.30V of one another (electrode potential at 25° C. and based upon a standard hydrogen electrode potential of zero). It is also desirable that the materials be selected so that the electrode potential of each electrical connector segment is within about 0.65 V or less, more preferably within about 0.30V or less as compared to the electrode potential of the cell surface materials (the top contact layer or backside substrate) that each connector segment is in contact with. The similarity of the electrode potential functions to reduce corrosive interactions between the cell surfaces and electrical connector segments.

Conductive materials having reduced hardness demonstrate improved function by providing higher contact area and thus lower initial contact resistance between the cell surfaces and the surfaces of the electrical connector segments. In addition, this reduced contact resistance produces higher initial power within the cells. Improved function is also recognized from the use of dissimilar electrical connector segment materials having electrode potential values that are similar. In addition, improved function is recognized from the use of electrical connector segment materials having electrode potential values that are similar to the electrode potential values of the cell surfaces that each electrical connector segments is in contact with. Such materials may include but are not limited to tin, silver, copper and combinations thereof. One preferred material for forming one or more electrical connector segments may be a copper core material having a tin coating.

It is contemplated that the photovoltaic article may further comprise optional encapsulant layers that may perform several functions. For example, the encapsulant layers may serve as a bonding mechanism, helping hold the adjacent layers of the module together. The use of such encapsulant layers traditionally may present connection issues in that the encapsulant may flow underneath a connector thereby reducing the contact area between the connector and the cell surface. However, in utilizing the electrical connector segments as taught herein, the electrical contact formed between the electrical connector surfaces and cell surfaces substantially prevents the flow of the encapsulant between the connector and cell surface.

Additional front and backside barrier layers may also be used. Front side barriers must be selected from transparent or translucent materials. These materials may be relatively rigid or may be flexible. Glass is highly useful as a front side environmental barrier to protect the active cell components from moisture, impacts and the like. A flexible barrier may also be employed which may include polymeric film materials. A backside barrier or backsheet may also be used. It is preferably constructed of a flexible material (e.g. a thin polymeric film, a metal foil, a multi-layer film, or a rubber sheet). In a preferred embodiment, the back sheet material may be moisture impermeable and also range in thickness from about 0.05 mm to 10.0 mm, more preferably from about 0.1 mm to 4.0 mm, and most preferably from about 0.2 mm to 0.8 mm. Other physical characteristics may include, elongation at break of about 20% or greater (as measured by ASTM D882); tensile strength or about 25 MPa or greater (as measured by ASTM D882); and tear strength of about 70 kN/m in or greater (as measured with the Graves Method). Examples of preferred materials include glass plate, aluminum foil, Tedlar® (a trademark of DuPont) or a combination thereof. A supplemental barrier sheet may also be employed which is connectively located below the back sheet. The supplemental barrier may be a composite material such as Protekt® (available from Madico, Inc., Woburn, Mass.). The supplemental barrier sheet may act as a barrier, protecting the layers above from environmental conditions and from physical damage that may be caused by any features of the structure on which the photovoltaic device is subjected to (e.g. for example in a roof deck (in the case of roofing BIPV products), protruding objects or the like). It is contemplated that this is an optional layer and may not be required. Alternatively, the protective layer could be comprised of more rigid materials so as to provide additional roofing function under structural and environmental (e.g. wind) loadings. Additional rigidity may also be desirable so as to improve the coefficient of thermal expansion of the photovoltaic device and maintain the desired dimensions during temperature fluctuations. Examples of protective layer materials for structural properties include polymeric materials such polyolefins, polyester amides, polysulfone, acetal acrylic, polyvinyl chloride, nylon, polycarbonate, phenolic, polyetheretherketone, polyethylene terephthalate epoxies, including glass and mineral filled composites or any combination thereof.

The figures discussed below include references to location of and contact between the photovoltaic cells and electrical connector segments taught herein. It should be noted that any discussion of contact between the components shown in the figures and discussed below may be direct contact or may be indirect contact through one or more layers commonly utilized in photovoltaic devices which may include adhesives, solder, coatings, or other materials necessary to form the desired electrical connections in and among the photovoltaic cells.

FIG. 1 shows a cross sectional view of an exemplary article in accordance with the present teachings showing two adjacent photovoltaic cells 10, 12. The first cell 10 is located in planar contact with a base substrate 14. A top contact layer 18 may be formed onto the first cell and a first electrical connector segment 22 may be located onto the top contact layer. The second cell 12 is also located onto a substrate 16, which forms the backside electrode of the second cell 12 and may be substantially similar in material to the substrate 14 for receiving the first cell. A top contact layer 20 is located in contact with the second cell, which may be substantially similar to the top contact layer 18 located onto the first cell. A second electrical connector segment 24 is located M contact with the substrate 16 of the second cell. The first and second electrical connector segments 22, 24 are located adjacent one another and connected to one another along a terminal edge 30, 32 of each of the electrical connector segments.

As shown for example in FIG. 2, the first and second electrical connector segments 22, 24 may each be formed of a first surface 34, 38 (comprising a first material layer) and a second surface 36, 40 (comprising a second material layer dissimilar from the first material layer) whereby each first surface is located in planar contact with each second surface. Thus, the second surface 36 of the first electrical connector segment 22 is located in planar contact with the top contact layer 18 of the first cell 10, and the first surface 38 of the second electrical connector segment 24 is located in planar contact with the substrate (e.g., the backside substrate for forming the backside electrode) 16 of the second cell 12. FIG. 3 depicts an arrangement whereby the first and second electrical connector segments are formed of dissimilar coating materials. More specifically, the first electrical connector segment 22 includes a first surface 34 and an opposing second surface 36. Both the first surface and opposing second surface are formed of a first coating material 26 and the coating material on the second surface is located in contact with the top contact layer 18 of the first cell. The second electrical connector segment 24 also includes a first surface 38 and opposing second surface 40 whereby the first surface and opposing second surface are thrilled of a second coating material 28. The second coating material forming the first surface 38 is located in contact with the backside substrate 16 of the second cell.

As shown for example in FIG. 4, the first electrical connector segment 22 includes a first surface 34 and an opposing second surface 36 whereby a first coating material 26 is located onto the second opposing, surface for forming the first electrical connector segment. A second coating material 28 is located onto the first Surface of the first electrical connector segment. The first coating material 26 also extends onto the second opposing surface 40 of the second electrical connector segment and the second coating material 28 extends onto the first surface 38 for forming the second electrical connector segment. Thus, the first coating material 26 forming the first electrical connector segment is located in contact with the top contact layer 18 and the second coating material 28 forming the second electrical connector segment is located in contact with the backside substrate 16. FIG. 5 depicts an exemplary device haying a first coating material 26 located in contact with the second opposing surface 36 for forming the first electrical connector segment. The first coating material 26 may also be located onto the second opposing surface 40 of the second electrical connector segment. A second coating material 28 is located in contact with the first surface 38 for forming the second electrical connector segment so that the second coating material contacts the backside substrate 16.

Any numerical values recited in the above application include all values from the lower value to the upper value in increments of one unit provided that there is a separation of at least 2 units between any lower value and any higher value. As an example, if it is stated that the amount of a component or a value of a process variable such as, for example, temperature, pressure, time and the like is, for example, from 1 to 90, preferably from 20 to 80, more preferably from 30 to 70, it is intended that values such as 15 to 85, 22 to 68, 43 to 51, 30 to 32 etc. are expressly enumerated in this specification. For values which are less than one, one unit is considered to be 0.0001, 0.001, 0.01 or 0.1 as appropriate. These are only examples of what is specifically intended and all possible combinations of numerical values between the lowest value and the highest value enumerated are to be considered to be expressly stated in this application in a similar manner. Unless otherwise stated, all ranges include both endpoints and all numbers between the endpoints. The use of “about” or “approximately” in connection with a range applies to both ends of the range. Thus, “about 20 to 30” is intended to cover “about 20 to about 30”, inclusive of at least the specified endpoints. The term “consisting essentially of” to describe a combination shall include the elements, ingredients, components or steps identified, and such other elements ingredients, components or steps that do not materially affect the basic and novel characteristics of the combination. The use of the terms “comprising” or “including” to describe combinations of elements, ingredients, components or steps herein also contemplates embodiments that consist essentially of the elements, ingredients, components or steps. Plural elements, ingredients, components or steps can he provided by a single integrated element, ingredient, component or step. Alternatively, a single integrated element, ingredient, component or step might be divided into separate plural elements, ingredients, components or steps. The disclosure of “a” or “one” to describe an element, ingredient, component or step is not intended to foreclose additional elements, ingredients, components or steps.

What is claimed is:

1. An article comprising:
(i) one or more photovoltaic cells having a first surface and an opposing second surface;
(ii) a first electrical connector segment having a portion that contacts and is in electrical communication with the first surface of the one or more cells;
(iii) a second electrical connector segment having a portion that contacts and is in electrical communication with the second surface of the one or more cells and is in electrical communication with the first electrical connector;
wherein the portion of the second electrical connector segment that contacts the second surface of the one or more cells comprises a material that is dissimilar from the material comprising the portion of the first electrical connector that contacts the first surface of the one or more cells.

2. The article of claim 1, wherein the first electrical connector segment contacts a first surface of a first cell and the second electrical connector segment contacts a second surface of a second adjacent cell.

3. The article of claim 1, wherein the first electrical connector segment comprises a material having a first electrode potential and the first surface of the one or more cells comprises a material having a first surface electrode potential so that the first electrode potential and first surface electrode potential differ by 0.3V or less at 25° C. based on a standard hydrogen electrode of zero volts.

4. The article of claim 1, wherein the second electrical connector segment comprises a material having a second electrode potential and the second surface of the one or more cells comprises a material having a second surface electrode potential so that the second electrode potential and second surface electrode potential differ by 0.3V or less at 25° C. based on a standard hydrogen electrode of zero volts.

5. The article of claim 1, wherein one or more of the first electrical connector segment and second electrical connector segment comprises a material having a hardness of 300 MPa or less on the Vickers hardness scale.

6. The article of claim 1, wherein the first electrical connector segment comprises a material selected from: tin, copper, silver, gold platinum, aluminum, molybdenum, zinc, antimony, niobium, chromium, nickel, indium, lead, iron, steel, stainless steel, TiN, TaN, SnO₂, doped SnO₂, ITO, AZO, doped ZnO, graphene, conductive organic polymers, conductive small molecules or any combination thereof.

7. The article of claim 1, wherein the second electrical connector segment comprises a material selected from: tin, copper, silver, gold, platinum, aluminum, molybdenum, zinc, antimony, niobium, chromium, nickel, indium, lead, iron, steel, stainless steel, TiN, TaN, SnO₂, doped SnO₂, ITO, AZO, doped ZnO, graphene, conductive organic polymers, conductive small molecules or any combination thereof.

8. The article of claim 1, wherein the second electrical connector segment comprises molybdenum, copper, silver, or gold and forms an ohmic contact with a surface material of the one or more cells, another material of the second electrical connector segment, or both.

9. The article of claim 1, wherein a Sn/Se film is formed by contacting the second surface of the one or more cells with the second electrical connector segment.

10. The article of claim 1, wherein at least a portion of one or more of the first and second electrical connector segments are formed of a coating comprising a conductive material.

11. The article of claim 1, wherein the first electrical connector segment comprises a material having a first electrode potential and the second electrical connector segment comprises a material having a second electrode potential so that the first electrode potential and second electrode potential differ by 0.3 V or less at 25° C. based on a standard hydrogen electrode of zero volts.

12. The article of claim 1, wherein one core material forms at least a portion of both the first and second electrical connector segments and the first and second electrical connector segments are formed of coatings located onto the core material such that the coating on the first electrical connector segment is dissimilar from the coating on the second electrical connector segment.

13. The article of claim 1, wherein the first electrical connector segment comprises a first core material and the second electrical connector segment comprises a second core material and a coating for forming the first electrical connector segment is dissimilar from a coating for forming the second electrical connector segment.

14. The article of claim 1, wherein one core material forms at least a portion of both the first and second electrical connector segments and the first and second electrical connector segments are formed of coatings located onto the core material such that a first coating on a first surface of the first electrical connector segment is the same as a coating on a first surface of the second electrical connector segment and a second coating on a second surface of the first electrical connector segment is the same as the coating on a second surface of the second electrical connector segment.

15. The article of claim 1, wherein the first and or second electrical connector segments are formed of a copper mesh having a coating selected from the group consisting of tin, an electrically conductive adhesive, or combinations thereof.

16. The article of claim 1, wherein the first surface of the one or more photovoltaic cells has a different surface composition than the surface composition of the opposing second surface.

17. The article of claim 1, wherein the first surface of the one or more photovoltaic cells comprises a topside electrode comprising a transparent conducting oxide and the opposing second surface comprises a backside electrode comprising a metal foil or film or a metal past or coating on a conductive or non-conductive substrate.

18. The article of claim 1, wherein the backside electrode comprises a substrate having a selenide, sulfide, or telluride surface content and the second electrical connector segment comprises specific metallurgy for bonding to the selenide, sulfide, or telluride surface.
